(19) United States
(12) Patent Application Publication
(10) Pub. No.: US 2016/0354871 A1
(43) Pub. Date: Dec. 8, 2016

(54) FLUX AND METHOD FOR MANUFACTURING SEMICONDUCTOR DEVICE

(71) Applicant: FUJITSU LIMITED, Kawasaki-shi (JP)

(72) Inventors: KOZO SHIMIZU, Atsugi (JP); Seiki Sakuyama, Yamato (JP); Nobuhiro Imaizumi, Atsugi (JP)

(73) Assignee: FUJITSU LIMITED, Kawasaki-shi (JP)

(21) Appl. No.: 15/097,516

(22) Filed: Apr. 13, 2016

(30) Foreign Application Priority Data
Jun. 3, 2015 (JP) 2015-112995

(51) Int. Cl. B23K 35/36; B23K 35/362; H01L 23/00

(52) U.S. Cl. CPC B23K 35/3613; H01L 24/81; B23K 35/362; H01L 2224/81815; H01L 2224/81024; H01L 2924/014; H01L 2224/16238; H01L 2224/81193; H01L 2224/81203; H01L 2224/13111; H01L 2224/13139; H01L 2924/2064; H01L 2924/20641; B23K 2201/40

(57) ABSTRACT

A flux includes: a first glycol-based polyhydric alcohol having a molecular weight of 300 or less; and a second glycol-based polyhydric alcohol having a molecular weight of 600 or more.

### CROSS-REFERENCE TO RELATED APPLICATION

This application is based upon and claims the benefit of priority from the prior Japanese Patent Application No. 2015-112995, filed on Jun. 3, 2015, the entire contents of which are incorporated herein by reference.

### FIELD

The embodiments discussed herein are related to a flux and a method for manufacturing a semiconductor device.

### BACKGROUND

A flux is used when a semiconductor chip or a semiconductor package is bonded with a circuit board by soldering.

Related techniques are disclosed in, for example, Japanese Laid-open Patent Publication No. 2011-083809, Japanese Laid-open Patent Publication No. 2004-001030, and Japanese Laid-Open Patent Publication No. 05-245689.

### SUMMARY

According to one aspect of the embodiments, a flux includes: a first glycol-based polyhydric alcohol having a molecular weight of 300 or less; and a second glycol-based polyhydric alcohol having a molecular weight of 600 or more.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1A, FIG. 1B, and FIG. 1C illustrate an example of a method for manufacturing a semiconductor device using flux;

FIG. 2 illustrates an example of a method for manufacturing a semiconductor device using flux;

FIG. 3A and FIG. 3B illustrate an example of a semiconductor device manufactured using flux;

FIG. 4A and FIG. 4B illustrate an example of a semiconductor device manufactured using flux;

FIG. 5 illustrates an example of a flux component table;

FIG. 6 illustrates an example of a flux component table, and

FIG. 7 illustrates an example of a flux component table.

### DESCRIPTION OF EMBODIMENTS

As for the flux, for example, a rosin-based flux containing rosin as a main component or a water-soluble flux containing halogen such as chlorine is used. The flux residues that remain after the solder bonding are removed by, for example, a cleaning using an organic solvent such as isopropyl alcohol (IPA) or a water cleaning.

For example, when terminals or electrodes of a bonding portion of a semiconductor chip or semiconductor package with a circuit board are miniaturized and gaps between the terminals or the electrodes are narrowed, it may be difficult to remove the flux residues. When rosin-based flux or water-soluble flux is used, halogen or the like may be mixed into, for example, an insulting film formed between electrodes on a substrate by the flux component or the flux residues such that the insulting film is swollen or peeled off. For example, an insulation property of the insulting film may be deteriorated due to ion migration.

For example, a polyhydric alcohol is used as a flux material.

For example, the polyhydric alcohol may be used as the flux material in order to reduce the swelling or peeling off of the insulting film caused by the flux residues and deterioration of the insulation property of the insulting film caused by ion migration. For example, the polyhydric alcohol having a lower molecular weight may be used in order to reduce the amount of flux residues.

In a case where the polyhydric alcohol having a lower molecular weight is used, excellent solder bonding may not be obtained. Therefore, it may be desirable to provide a technique capable of obtaining excellent solder bonding while reducing the amount of flux residues.

The flux may be a soldering flux that is used when a semiconductor device is manufactured by solder-bonding, for example, flip-chip-bonding using solder bumps a semiconductor package or a semiconductor chip such as, for example, an LSI chip, with a circuit board and mounting the semiconductor chip or the semiconductor package on the circuit board. The semiconductor chip may be referred to as a semiconductor element and the circuit board may be referred to as a circuit wiring board.

For example, the flux has an action for reducing an oxide film on a surface of a solder such as, for example, a surface of a solder bump, or an oxide film on a surface of an electrode to be bonded by soldering such as, for example, an electrode pad on a substrate. The flux may contain a first glycol-based polyhydric alcohol having a molecular weight (average molecular weight) of 300 or less and a second glycol-based polyhydric alcohol having a molecular weight (average molecular weight) of 600 or more.

The first glycol-based polyhydric alcohol having a molecular weight of 300 or less may be, for example, a polyethylene glycol (PEG) or a tetraethylene glycol (TEG). The polyethylene glycol has a molecular weight of 200 or more and 300 or less and is a liquid at a normal temperature. The tetraethylene glycol has a molecular weight of 194 and is a liquid at a normal temperature. The second glycol-based polyhydric alcohol having a molecular weight of 600 or more may be, for example, a polyethylene glycol. The polyethylene glycol has a molecular weight of 600 or more and 1,000 or less and is a liquid at a normal temperature.

For example, the first glycol-based polyhydric alcohol may be the polyethylene glycol having a molecular weight of 200 or more and 300 or less and the second glycol-based polyhydric alcohol may be the polyethylene glycol having a molecular weight of 600 or more and 1,000 or less. For example, the first glycol-based polyhydric alcohol may be the tetraethylene glycol having a molecular weight of 194 and the second glycol-based polyhydric alcohol may be the polyethylene glycol having a molecular weight of 600 or more and 1,000 or less.

The flux may contain the first glycol-based polyhydric alcohol (first liquid) having a molecular weight of 300 or less and the second glycol-based polyhydric alcohol (second liquid) having a molecular weight of 600 or more as main components (main agents), or may be a mixture of these two components. For example, the flux material may be a mixture (mixed liquid; composition) of the first glycol-based polyhydric alcohol having a molecular weight of 300 or less, for example, a polyhydric alcohol having a lower molecular weight, and the second glycol-based polyhydric alcohol having a molecular weight of 600 or more, for example, a polyhydric alcohol having a higher molecular weight.

For example, the terminals or electrodes of the bonding portion of the semiconductor chip or the semiconductor package with the circuit board are miniaturized so as to narrow the gaps between the terminals or the electrodes and thus, it may be difficult to remove the flux residues.

For example, a gap between a plurality of terminals provided on the semiconductor chip or the semiconductor package (e.g., a pitch size) or a gap between a plurality of electrodes provided on the circuit board (e.g., a pitch size) is from about 200 μm or more, through from about 100 μm or more to about 200 μm or less, to about 100 μm or less. As described above, in a case where the pitch size is narrowed and the gaps between the terminals or the electrodes are narrow, when the rosin-based flux or the water-soluble flux is used, the flux residues may not be completely removed even if the cleaning using an organic solvent such the IPA or water cleaning is performed after the mounting is conducted by soldering.

When the rosin-based flux or the water-soluble flux is used, halogen or the like may be mixed into, for example, an insulting film formed between electrodes on a substrate by the flux component or the flux residues such that the insulting film is swollen or peeled off. For example, an insulation property of the insulting film may be deteriorated due to ion migration. For example, an insulation property (e.g. an insulation resistance) of the insulting film may be reduced due to the ion migration started from the flux residues.

For example, the polyhydric alcohol, which does not contain, for example, halogen, may be used as the flux material in order to reduce the swelling or peeling off of the insulting film caused by the flux residues or deterioration of the insulation property of the insulting film caused by the ion migration. The polyhydric alcohol having a lower molecular weight may be used in order to reduce the amount of the flux residues.

For example, when the polyhydric alcohol having a lower molecular weight is used, excellent solder bonding may not be obtained. For example, when only the polyhydric alcohol having a lower molecular weight is used, the amount of flux residues is reduced, but solderability (solder wettability) is deteriorated and thus, excellent solder bonding may not be obtained.

For example, when only the polyhydric alcohol having a higher molecular weight is used, solderability is excellent and thus excellent solder bonding is obtained, but the amount of flux residues may be increased. For this reason, the flux material may be a mixture of the polyhydric alcohol having a lower molecular weight and the polyhydric alcohol having a higher molecular weight. Thus, the solderability is excellent while the amount of flux residues is reduced, so that excellent solder bonding may be obtained.

For example, excellent solder bonding may be obtained compared to a case where the flux contains only the polyhydric alcohol having a lower molecular weight. For example, the amount of flux residues is reduced compared to a case where the flux contains only the polyhydric alcohol having a higher molecular weight, and thus, for example, the filling property of an underfill may be enhanced. A volatilization temperature of the polyhydric alcohol having a lower molecular weight is low and a volatilization temperature of the polyhydric alcohol having a higher molecular weight is high.

For example, the volatilization temperature of the polyhydric alcohol having a lower molecular weight may be set to be lower than a reflow temperature of solder and the volatilization temperature of the polyhydric alcohol having a higher molecular weight may be set to be higher than a reflow temperature of solder. A reflow temperature of solder is a temperature for reflowing (melting) the solder at the time of the solder bonding and may be higher than the melting point of the solder. The reflow temperature of solder may be referred to as a bonding temperature, a soldering temperature, or a heating temperature.

For example, SnAg based solder may be used in the solder bonding. The reflow temperature of solder is a temperature higher than a melting point of the SnAg based solder (e.g., about 217° C.), for example, a temperature of about 300° C. to 380° C. In this case, the volatilization temperature of the polyhydric alcohol having a lower molecular weight may be set to be lower than a reflow temperature of SnAg based solder and the volatilization temperature of the polyhydric alcohol having a higher molecular weight may be set to be higher than a reflow temperature of SnAg based solder. For example, the volatilization temperature of the first glycol-based polyhydric alcohol may be set to be lower than a reflow temperature of SnAg based solder and the volatilization temperature of the second glycol-based polyhydric alcohol may be set to be higher than a reflow temperature of SnAg based solder.

When the solder is heated to the reflow temperature of solder at the time of conducting the solder bonding, most of the polyhydric alcohol having a lower molecular weight is volatilized and thus, the amount of flux residues is reduced. In the meantime, most of the polyhydric alcohol having a higher molecular weight are not volatilized and left, and demonstrates a reducing action. Therefore, solderability is excellent and excellent solder bonding may be obtained. The flux material may be a mixture of the polyhydric alcohol having a lower molecular weight and the polyhydric alcohol having a higher molecular weight, and does not contain, for example, a rosin, a thixo-agent, or an amine salt which is a kind of a component of activation agent that become a factor causing the flux residues.

Therefore, the amount of the flux residues may be reduced. The components, such as halogen or amine salt, that are harmful to, for example, the insulting film, such as a resist, formed between the electrodes on the substrate are not contained in the flux material. Therefore, swelling or peeling off of the insulting film caused by the flux residues is reduced and deterioration of the insulation property of the insulting film caused by ion migration is reduced.

Since the amount of flux residues is reduced, the flux residues may be completely removed by, for example, a water cleaning. The amount of flux residues may be reduced to the extent that the flux residues may be completely removed by, for example, a water cleaning. For example, the amount of flux residues may be reduced by a mixing ratio of the polyhydric alcohol having a lower molecular weight and the polyhydric alcohol having a higher molecular weight or by a reflow temperature at the time of the solder bonding, and in this case, non-cleaning bonding may be conducted.

The flux may contain more in the first glycol-based polyhydric alcohols than the second glycol-based polyhydric alcohols. For example, a composition ratio (e.g., a volume ratio) of the first glycol-based polyhydric alcohol having a lower molecular weight in the flux may be greater than about 50% (e.g., about 50 vol %). Accordingly, the amount of flux residues is further reduced and thus, the flux residues may be removed by, for example, a non-cleaning or a water cleaning.

A mixing ratio of the first glycol-based polyhydric alcohol having a higher molecular weight which causes the flux residues may be made small so as to further reduce the amount of flux residues without deteriorating solderability. Since the amount of flux residues is further reduced, for example, the filling property, such as an underfill may be enhanced. For example, an average molecular weight of the first glycol-based polyhydric alcohol having a lower molecular weight and the second glycol-based polyhydric alcohol having a higher molecular weight in the flux may be less than about 600. For example, the composition ratio (e.g., a volume ratio) of the first glycol-based polyhydric alcohol having a lower molecular weight in the flux may be greater than about 50% (e.g., about 50 vol %), and the average molecular weight of the first glycol-based polyhydric alcohol having a lower molecular weight and the second glycol-based polyhydric alcohol having a higher molecular weight in the flux may be less than about 600.

The amount of flux residues is further reduced and thus, the flux residues may be removed by, for example, a non-cleaning or a water cleaning. The flux may contain other materials in addition to the first glycol-based polyhydric alcohol having a molecular weight of 300 or less and the second glycol-based polyhydric alcohol having a molecular weight of 600 or more.

For example, a minute amount of an organic acid or an organic acid anhydride may be added. For example, the flux may contain the first glycol-based polyhydric alcohol having a molecular weight of 300 or less and the second glycol-based polyhydric alcohol having a molecular weight of 600 or more, and may further contain an organic acid or an organic acid anhydride. The solder wettability is enhanced by the addition and thus solderability may also be enhanced.

In this case, the flux contains the first glycol-based polyhydric alcohol having a molecular weight of 300 or less, the second glycol-based polyhydric alcohol having a molecular weight of 600 or more, and the organic acid or the organic acid anhydride. The organic acid may be, for example, succinic acid, sebacic acid, adipic acid, L-glutamic acid, glutaric acid, stearic acid, palmitic acid, abietic acid, malonic acid, benzoic acid, or carboxylic acid. The organic acid anhydride may be, for example, anhydrides of those organic acids such as succinic anhydride. The organic acid may not contain amine salt in order to reduce the peeling off of the insulting film formed on the surface of the substrate.

In a case where main components of the flux are the first glycol-based polyhydric alcohol and the second glycol-based polyhydric alcohol, the contents of the first glycol-based polyhydric alcohol and the second glycol-based polyhydric alcohol in the flux may be about 80% or more. For example, the material containing about 80% or more of the first glycol-based polyhydric alcohol and the second glycol-based polyhydric alcohol in volume ratio may be used as the flux.

For example, when the flux contains the first glycol-based polyhydric alcohol having a molecular weight of 300 or less and the second glycol-based polyhydric alcohol having a molecular weight of 600 or more, the ratio of the contents of the first glycol-based polyhydric alcohol and the second glycol-based polyhydric alcohol in the flux is about 100%. When the flux contains the first glycol-based polyhydric alcohol having a molecular weight of 300 or less, the second glycol-based polyhydric alcohol having a molecular weight of 600 or more, and the organic acid or the organic acid anhydride, the contents of the first glycol-based polyhydric alcohol and the second glycol-based polyhydric alcohol (contents of main components) in the flux may be about 80% or more.

In a method for manufacturing a semiconductor device, the semiconductor chip or the semiconductor package is bonded with the circuit board by reflowing the SnAg based solder using the flux described above.

For example, when a gap between a plurality of terminals of a bonding portion of the semiconductor chip or the semiconductor package with the circuit board is 100 μm or less, the semiconductor chip or the semiconductor package may be bonded with the circuit board by reflowing the SnAg based solder using the flux described above. Since a plurality of terminals provided on the semiconductor chip or the semiconductor package and a plurality of electrodes (electrode pads) provided on the circuit board are bonded by soldering, the gap between the plurality of terminals is substantially the same as the gap between the plurality of electrodes. When the gap between the plurality of terminals is 100 μm or less, the gap between the plurality of electrodes is also 100 μm or less. Accordingly, when the gap between the plurality of electrodes of the bonding portion of the semiconductor chip or the semiconductor package with the circuit board is 100 μm or less, the semiconductor chip or the semiconductor package may be bonded with the circuit board by reflowing the SnAg based solder using the flux described above.

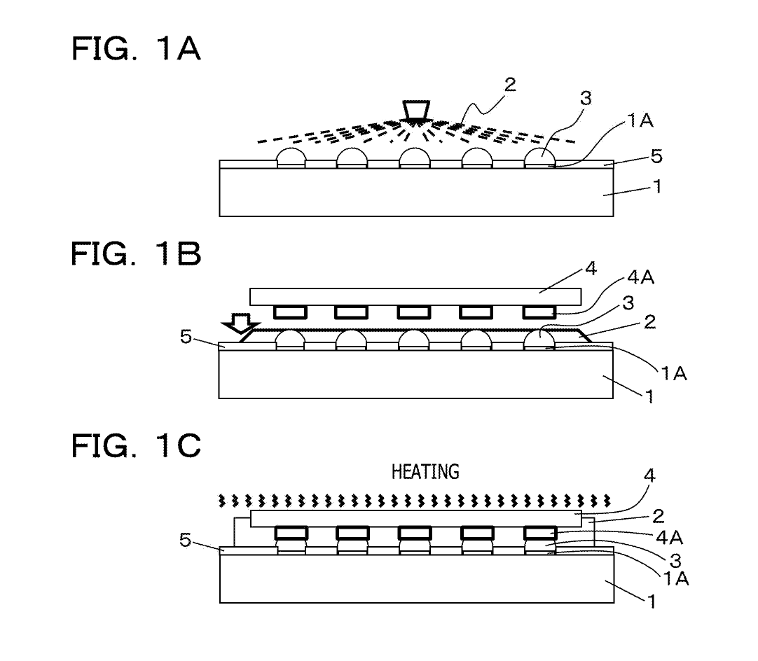

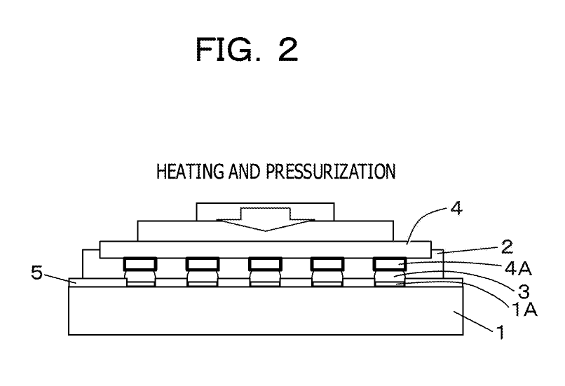

FIG. 1A to FIG. 1C and FIG. 2 illustrate an example of a method for manufacturing a semiconductor device using flux. As illustrated in FIG. 1A, a flux 2 as described above is applied, for example, by a spraying, on a surface of a circuit board 1 including a plurality of electrodes 1A and an insulting film 5 and then, SnAg based solders 3 (solder balls; solder bumps) are formed on the plurality of electrodes 1A provided on the circuit board 1. The flux 2 described above is applied by, for example, a spraying, in a state where the SnAg based solders 3 are formed on the plurality of electrodes 1A provided on the circuit board 1.

As illustrated in FIG. 1B, a positional alignment of a plurality of terminals 4A, for example, Cu pillars provided on the semiconductor chip 4 (or semiconductor package) and the plurality of electrodes 1A provided on the circuit board 1, for example, the SnAg based solders 3 formed on the plurality of electrodes 1A is performed. The semiconductor chip 4 or the semiconductor package is mounted on the circuit board 1. As illustrated in FIG. 1C or FIG. 2, the SnAg based solders 3 is reflowed by being heated to the reflow temperature of the SnAg based solders 3 such that the plurality of terminals 4A provided on the semiconductor chip 4 or the semiconductor package and the plurality of electrodes 1A provided on the circuit board 1 are bonded (flip-chip bonding) with each other by the SnAg based solders 3, respectively.

A reflow furnace may be used (see, e.g., FIG. 1C) or a flip chip bonder (FCB) may be used (see, e.g., FIG. 2) in order to bond the terminals and electrodes by reflowing the SnAg based solders 3. For example, the semiconductor chip 4 (or semiconductor package) and the circuit board 1 may be bonded with each other by being heated with a reflow furnace, for example, bonded by a reflow soldering. In this case, heating may be performed using the reflow furnace. For example, the semiconductor chip 4 (or semiconductor package) and the circuit board 1 may be bonded (FCB local reflow bonding) with each other by being subjected to heating and pressurization (thermo-compression bonding) using the FCB by, for example, FCB local reflow soldering. In this case, the heating and pressurization may be performed using the FCB.

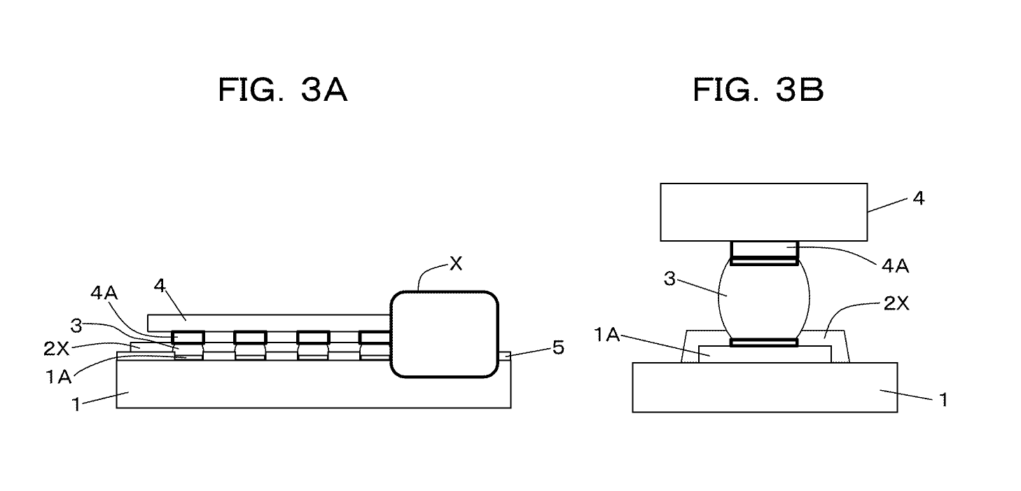

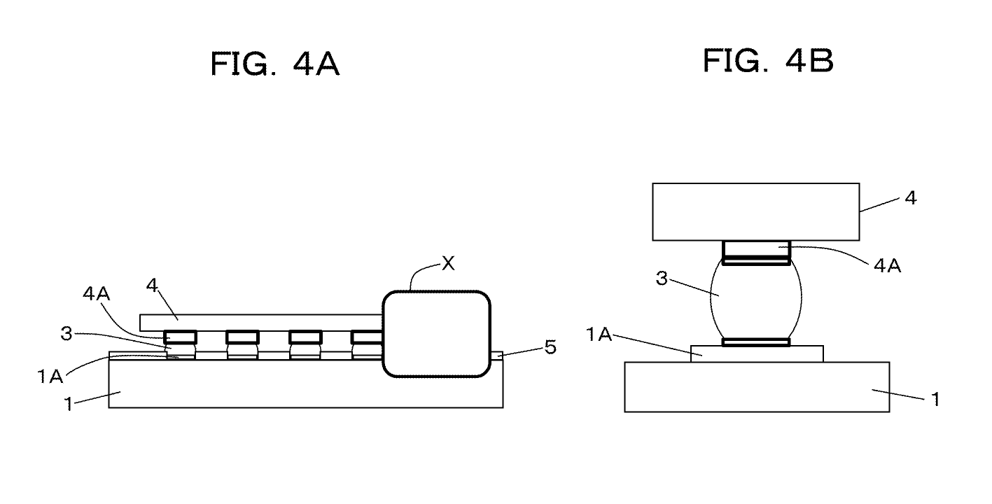

FIG. 3A and FIG. 3B illustrate an example of a semiconductor device manufactured using flux. In FIG. 3B, an enlarged diagram of a portion denoted by a reference numeral X of FIG. 3A is illustrated. FIG. 4A and FIG. 4B illustrate an example of a semiconductor device manufactured using flux. In FIG. 4B, an enlarged diagram of a portion denoted by a reference numeral X of FIG. 4A is illustrated. When the semiconductor chip 4 (or semiconductor package) and the circuit board 1 are bonded by the SnAg based solders 3 using the flux 2 described above, as illustrated in FIG. 3A and FIG. 3B, excellent solder bonding may be obtained while reducing the amount flux residues 2X. The insulting film 5 is not illustrated in FIG. 3B. After bonding is performed as described above, the flux residues 2X may be completely removed by cleaning (e.g., flux cleaning) such as, a water cleaning, for example, at about 80° C., as illustrated in FIG. 4A and FIG. 4B. The insulting film 5 is not illustrated in FIG. 4B.

Thereafter, an underfill is filled in the semiconductor device to be cured. With the processes described above, the semiconductor device in which the semiconductor chip 4 (or semiconductor package) is mounted (e.g., a flip-chip mounting) on the circuit board 1 is manufactured (see, e.g., FIG. 3 and FIG. 4). A semiconductor device having less flux residues, an excellent filling property of underfill, excellent solder bonding, and an excellent insulation property may be obtained.

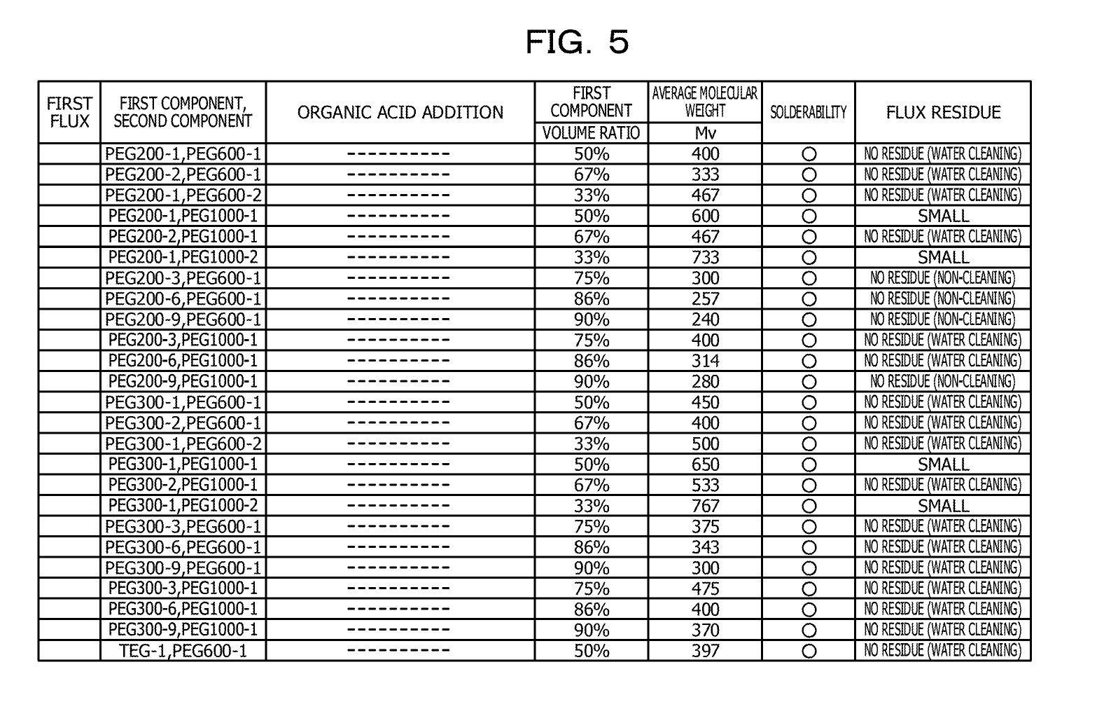

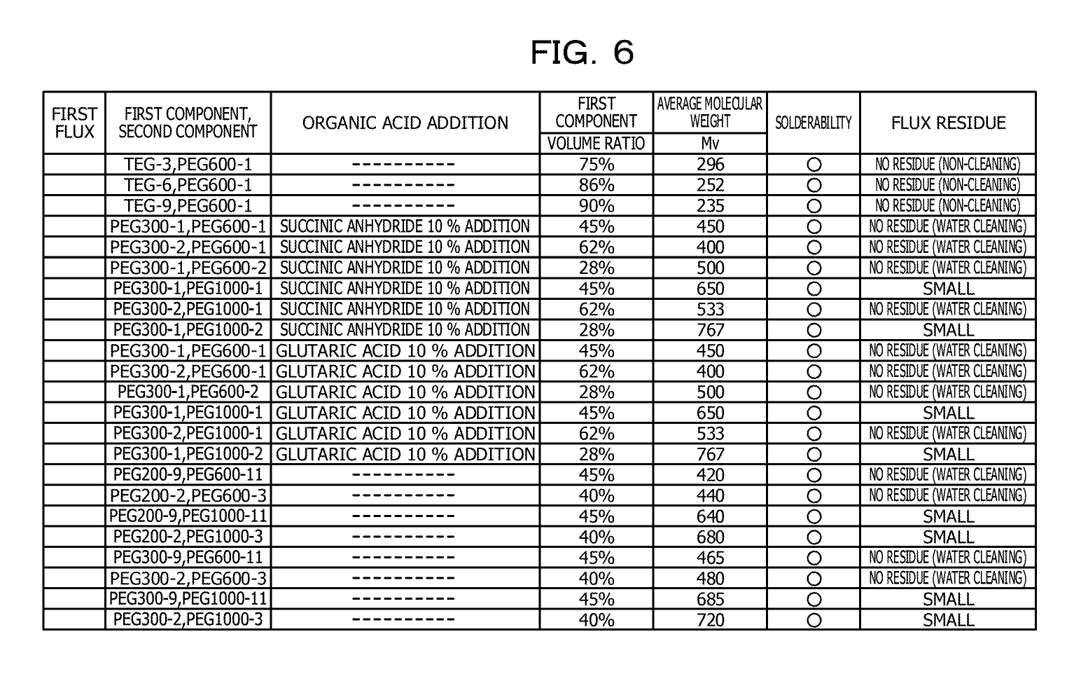

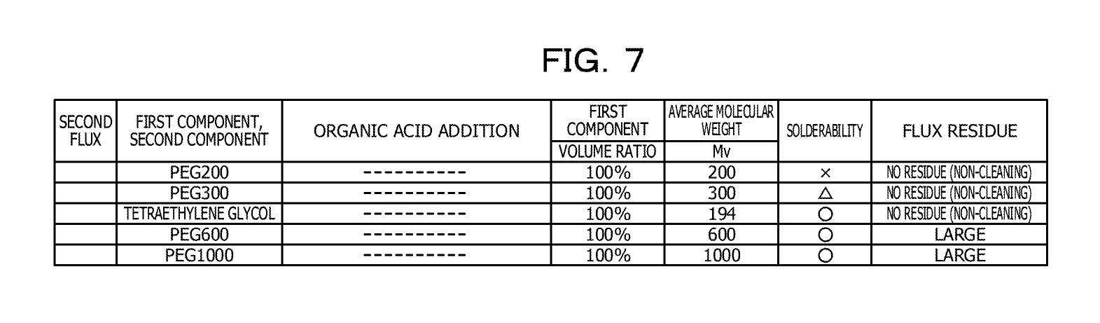

FIG. 5, FIG. 6, and FIG. 7 illustrate an example of a flux component table. In FIG. 5, a first component, a second component, presence or absence of addition of organic acid or the like, a volume ratio, an average molecular weight, and evaluation results for a solderability and flux residues, on each of first fluxes of 1 to 25, are represented. In FIG. 6, a first component, a second component, presence or absence of addition of organic acid or the like, a volume ratio, an average molecular weight, and evaluation results for a solderability and flux residues, on each of first fluxes of 26 to 48, are represented. In FIG. 7, a first component, a second component, presence or absence of addition of organic acid or the like, a volume ratio, an average molecular weight, and evaluation results for a solderability and flux residues, on each of second fluxes of 1 to 5 are represented. For example, the first fluxes of 1 to 48 (see, e.g., FIG. 5 and FIG. 6) and the second fluxes of 1 to 5 (see, e.g., FIG. 7) are applied on the surface of the circuit board 1 including the plurality of electrodes 1A (pitch size of about 80 μm). Thereafter, the SnAg based solders 3 (solder bumps having a diameter of about 40 μm) are formed on the plurality of electrodes 1A provided on the circuit board 1. The first fluxes of 1 to 48 (see, e.g., FIG. 5 and FIG. 6) and the second fluxes of 1 to 5 (see, e.g., FIG. 7) are applied (see, e.g., FIG. 1A) in a state where the SnAg based solders 3 are formed on the plurality of electrodes 1A provided on the circuit board 1. A positional alignment of the plurality of terminals 4A provided on the semiconductor chip 4 (pitch size of about 80 μm) and the SnAg based solders 3 formed on the plurality of electrodes 1A provided on the circuit board 1 is performed (see, e.g., FIG. 1B) and the semiconductor chip 4 is mounted on the circuit board 1. The SnAg based solders 3 are reflowed by being heated to the reflow temperature of the SnAg based solders 3, for example, a set temperature of about 340° C. or actual measurement temperature of about 300° C. in order to bond the semiconductor chip 4 and the circuit board 1 (see, e.g., FIG. 1C and FIG. 2), and thus, the semiconductor device in which the semiconductor chip 4 is flip-chip mounted on the circuit board 1 is manufactured (see, e.g., FIG. 3 and FIG. 4).

The solderability and flux residues are evaluated. The first fluxes of 1 to 28 and 41 to 48 are different from each other in a molecular weight or a component ratio of the first glycol-based polyhydric alcohol having a lower molecular weight of 300 or less contained in the flux, and a molecular weight or a component ratio of the second glycol-based polyhydric alcohol having a higher molecular weight of 600 or more contained in the flux. In the first fluxes of 29 to 40, the organic acid or the organic acid anhydride is added. The second fluxes of 1 to 3 contain only the first glycol-based polyhydric alcohol having a lower molecular weight of 300 or less. The second fluxes of 4 and 5 contain only the second glycol-based polyhydric alcohol having a higher molecular weight of 600 or more.

In FIG. 5 to FIG. 7, regarding the first component (e.g., first glycol-based polyhydric alcohol having a molecular weight of 300 or less) and the second component (e.g., second glycol-based polyhydric alcohol having a molecular weight of 600 or more) contained in the flux, a polyethylene glycol and a tetraethylene glycol are respectively written as PEG and TEG in the “first component, second component” field, and the molecular weight or the composition ratio is also written in the field. The organic acid or the organic acid anhydride is written in the “organic acid addition” field.

For example, in the first flux of 1, the first component is a polyethylene glycol having a molecular weight of 200 and the second component is a polyethylene glycol having a molecular weight of 600, and a composition ratio of the first component and the second component is 1:1. Therefore, the first component and the second component are respectively written as PEG200-1 and PEG600-1 in the “first component, second component” field. Since the organic acid or the organic acid anhydride is not contained, a reference symbol “ - - - ” is written in the “organic acid addition” field.

In the first flux of 2, the first component is a polyethylene glycol having a molecular weight of 200 and the second component is a polyethylene glycol having a molecular weight of 600, and a composition ratio of the first component and the second component is 2:1. Therefore, the first component and the second component are respectively written as PEG200-2 and PEG600-1 in the “first component, second component” field. Since the organic acid or the organic acid anhydride is not contained, a reference symbol “ - - - ” is written in the “organic acid addition” field.

In the first flux of 25, the first component is a tetraethylene glycol (molecular weight of 194) and the second component is a polyethylene glycol having a molecular weight of 600, and a composition ratio of the first component and the second component is 1:1. Therefore, the first component and the second component are respectively written as TEG-1 and PEG600-1 in the “first component, second component” field. Since the organic acid or the organic acid anhydride is not contained, a reference symbol “ - - - ” is written in the “organic acid addition” field.

In the first flux of 29, the first component is a polyethylene glycol having a molecular weight of 300 and the second component is a polyethylene glycol having a molecular weight of 600, and a composition ratio of the first component and the second component is 1:1. Therefore, the first component and the second component are respectively written as PEG300-1 and PEG600-1 in the “first component, second component” field. Since succinic anhydride is added by 10% as the organic acid or the organic acid anhydride, “succinic anhydride 10% addition” is written in the “organic acid addition” field.

In the second flux of 35, the first component is a polyethylene glycol having a molecular weight of 300 and the second component is a polyethylene glycol having a molecular weight of 600, and a composition ratio of the first component and the second component is 1:1. Therefore, the first component and the second component are respectively written as PEG300-1 and PEG600-1 in the “first component, second component” field. Since glutaric acid is added by 10% as the organic acid or the organic acid anhydride, “glutaric acid 10% addition” is written in the “organic acid addition” field.

Since the first flux of 48 contains only the polyethylene glycol having a molecular weight of 600, PEG600 is written in the “first component, second component” field. Since the organic acid or the organic acid anhydride is not contained, a reference symbol “ - - - ” is written in the “organic acid addition” field. The second flux of 3 contains only the tetraethylene glycol (molecular weight of 194). Accordingly, the tetraethylene glycol is written in the “first component, second component” field. Since the organic acid or the organic acid anhydride is not contained, a reference symbol “ - - - ” is written in the “organic acid addition” field.

Other first flux and second flux are written in the similar manner as described above. In FIG. 5 to FIG. 7, regarding the respective first flux and second flux, the volume ratio of the first component contained in the flux is written in the “first component/volume ratio” field and an average molecular weight of the first component and the second component contained in the flux is written in the “average molecular weight/Mv” field. Regarding the second flux, since the component contained in the flux is only the polyethylene glycol or the tetraethylene glycol, 100% is written in the “first component/volume ratio” field, and a molecular weight of the component contained in the flux is written in the “average molecular weight/Mv” field.

In FIG. 5 to FIG. 7, regarding the respective first flux and second flux, evaluation results for the solderability and the flux residues are written in the “solderability” field and “flux residue” field, respectively. As the evaluation for the solderability, it was determined whether solder bonding of each solder bonding portion is excellent in a sample having 620 solder bonding portions. When it is determined that all of the solder bonding portions are excellent in solder bonding, the reference symbol of “∘” is written in the “solderability” field. When it is determined that defective solder bonding occurred in some of the solder bonding portions, the reference symbol of “Δ is written in the “solderability” field. When it is determined that defective solder bonding occurred in all of the solder bonding portions, the reference symbol of “x” is written in the “solderability” field.

As the evaluation for the flux residues, in a case of non-cleaning and no flux residues, the expression of “no residue (non-cleaning)” is written in the “flux residue” field. In a case where the flux residues were removed by water cleaning, the expression of “no residue (water cleaning)” is written in the “flux residue” field. In a case where the flux residues were left even if water cleaning was conducted, but the amount of the remaining flux residues was small, the wording “small” is written in the “flux residue” field. In a case where the flux residues were left even if water cleaning was conducted and the amount of the remaining flux residues was large, the wording “large” is written in the “flux residue” field.

In the evaluation results for solderability, excellent solder bonding was not obtained in a case where the second fluxes of 1 to 3 were used as illustrated in FIG. 7, while excellent solder bonding was obtained in a case of where the first fluxes of 1 to 48 were used as illustrated in FIG. 5 and FIG. 6. In the polyethylene glycol having a molecular weight of 200 and contained in the second flux of 1, the volatilization staring point is 112.2° C. and the volatilization temperature is 249.5° C. In the polyethylene glycol having a molecular weight of 300 and contained in the second flux of 2, the volatilization staring point is 191.3° C. and the volatilization temperature is 295.6° C. In the tetraethylene glycol having a molecular weight of 194 and contained in the second flux of 3, the volatilization staring point is 110.8° C. and the volatilization temperature is 234.1° C. The volatilization staring point is a temperature at which weight loss of 10% or more has occurred in TG-DTA measurement (10° C./min). Further, the volatilization temperature is a temperature at which weight loss of 50% or more has occurred in TG-DTA measurement (10° C./min).

As described above, the second fluxes of 1 to 3 contain only the tetraethylene glycol or the polyethylene glycol having a lower molecular weight and the volatilization staring point and the volatilization temperature are not higher than the reflow temperature of the SnAg based solder. Therefore, in a case where the second fluxes of 1 to 3 were used, the flux does not effectively act when bonding is conducted by reflowing the SnAg based solder. As a result, excellent solder bonding was not obtained.

In the first fluxes of 1 to 48, the polyethylene glycol having a higher molecular weight is added to the tetraethylene glycol or the polyethylene glycol having a lower molecular weight. The polyethylene glycol having a molecular weight of 600 or the polyethylene glycol having a molecular weight of 1,000 is added as the polyethylene glycol having a higher molecular weight. In the polyethylene glycol having a molecular weight of 600, the volatilization staring point is 297.4° C. and the volatilization temperature is 385.5° C. In the polyethylene glycol having a molecular weight of 1,000, the volatilization staring point is 336.4° C. and the volatilization temperature is 393.4° C. The volatilization staring point is a temperature at which weight loss of 10% or more has occurred in TG-DTA measurement (10° C./min). The volatilization temperature is a temperature at which weight loss of 50% or more has occurred in TG-DTA measurement (10° C./min).

The volatilization staring point and the volatilization temperature of the polyethylene glycol having a higher molecular weight are higher than the reflow temperature of the SnAg based solder. As described above, in first fluxes of 1 to 48, the polyethylene glycol having a higher molecular weight and a higher volatilization staring point and a higher volatilization temperature is added to the polyethylene glycol or tetraethylene glycol having a lower molecular weight and the volatilization staring point and the volatilization temperature not higher than the reflow temperature of the SnAg based solder.

In this case, the volatilization staring point and the volatilization temperature of the flux obtained by mixing the polyethylene glycol or tetraethylene glycol having a lower molecular weight and the polyethylene glycol having a higher molecular weight is determined according to, for example, the volatilization staring point and the volatilization temperature of the polyethylene glycol or tetraethylene glycol having a lower molecular weight, the volatilization staring point and the volatilization temperature of the polyethylene glycol having a higher molecular weight, and a mixing ratio of the polyethylene glycol or tetraethylene glycol having a lower molecular weight and the polyethylene glycol having a higher molecular weight.

For example, in the first flux of 1, the polyethylene glycol having a molecular weight of 200 and the polyethylene glycol having a molecular weight of 600 are mixed in a ratio of 1:1. In the polyethylene glycol having a molecular weight of 200, the volatilization staring point is 112.2° C. and the volatilization temperature is 249.5° C. In the polyethylene glycol having a molecular weight of 600, the volatilization staring point is 297.4° C. and the volatilization temperature is 385.5° C. Therefore, the volatilization staring point and the volatilization temperature of the first flux of 1 obtained by mixing these polyethylene glycols are 147.8° C. and is 374.8° C., respectively. The volatilization staring point is a temperature at which weight loss of 10% or more has occurred in TG-DTA measurement (10° C./min). The volatilization temperature is a temperature at which weight loss of 50% or more has occurred in TG-DTA measurement (10° C./min). In the meantime, other first fluxes are similar as described above.

In a case where the first fluxes of 1 to 48 were used, when bonding is conducted by reflowing the SnAg based solder, the flux effectively acts, the solder is satisfactorily wet, and alloying is favorably progressed and thus, an excellent solder bonding may be obtained. In the evaluation results of the flux residues, as illustrated in FIG. 5 to FIG. 7, the amount of flux residues occurring in a case where the first fluxes of 1 to 48 are used is reduced compared to a case where the second fluxes of 4 and 5 are used.

In the polyethylene glycol having a molecular weight of 600 contained in the second flux of 4, the volatilization staring point is 297.4° C. and the volatilization temperature is 385.5° C. In the polyethylene glycol having a molecular weight of 1,000 contained in the second flux of 5, the volatilization staring point is 336.4° C. and the volatilization temperature is 393.4° C. The volatilization staring point is a temperature at which weight loss of 10% or more has occurred in TG-DTA measurement (10° C./min). Further, the volatilization temperature is a temperature at which weight loss of 50% or more has occurred in TG-DTA measurement (10° C./min).

As described above, the second fluxes of 4 and 5 contain only the polyethylene glycol having a higher molecular weight and the volatilization staring point and the volatilization temperature are higher than the reflow temperature of the SnAg based solder. Therefore, in a case where the second fluxes of 4 and 5 were used, although the flux effectively acts so that excellent solder bonding may be obtained when bonding is conducted by reflowing the SnAg based solder, a lot of flux residues may exist.

In contrast, in the first fluxes of 1 to 48, the polyethylene glycol or tetraethylene glycol having a lower molecular weight is added to the polyethylene glycol having a higher molecular weight, and a ratio of the polyethylene glycol having a higher molecular weight is lower compared to the second fluxes of 4 and 5. The polyethylene glycol having a molecular weight of 200 or the polyethylene glycol or the tetraethylene glycol having a molecular weight of 300 is added as the polyethylene glycol or the tetraethylene glycol having a lower molecular weight.

In the polyethylene glycol having a molecular weight of 200, the volatilization staring point is 112.2° C. and the volatilization temperature is 249.5° C. In the polyethylene glycol having a molecular weight of 300, the volatilization staring point is 191.3° C. and the volatilization temperature is 295.6° C. In the tetraethylene glycol having a molecular weight of 194, the volatilization staring point is 110.8° C. and the volatilization temperature is 234.1° C. The volatilization staring point is a temperature at which weight loss of 10% or more has occurred in TG-DTA measurement (10° C./min). The volatilization temperature is a temperature at which weight loss of 50% or more has occurred in TG-DTA measurement (10° C./min).

The volatilization staring point and the volatilization temperature of the polyethylene glycol or the tetraethylene glycol having a lower molecular weight are not higher than the reflow temperature of the SnAg based solder. As described above, in the first fluxes of 1 to 48, the polyethylene glycol or tetraethylene glycol having a lower molecular weight and the volatilization staring point and the volatilization temperature that are not higher than the reflow temperature of the SnAg based solder is added to the polyethylene glycol having a higher molecular weight and a volatilization staring point and a volatilization temperature that are higher than the reflow temperature of the SnAg based solder.

In a case where the first fluxes of 1 to 48 were used, when bonding is conducted by reflowing the SnAg based solder, the flux effectively acts and thus, an excellent solder bonding may be obtained. The amount of flux residues is reduced compared to a case where the second fluxes of 4 and 5 were used. As a result, the filling property of underfill or the like may be improved compared to a case where the second fluxes of 4 and 5 were used.

In a case where the first fluxes of 4, 6, 16, 18, 32, 34, 38, 40, 43, 44, 47, and 48 were used, for example, in a case where the flux having a composition ratio (volume ratio) of the first component of about 50% or less, and an average molecular weight of the first component and the second component of about 600 or more was used, the amount of flux residues was reduced compared to the second fluxes of 4 and 5 but, the flux residues were left even when water cleaning was conducted.

In a case where other first fluxes of 1 to 3, 5, 7 to 15, 17, 19 to 31, 33, 35 to 37, 39, 41, 42, 45, and 46 were used, for example, in a case where the flux having a composition ratio (volume ratio) of the first component of greater than about 50%, the flux having an average molecular weight of the first component and the second component, which is less than about 600, or the flux having a composition ratio (volume ratio) of the first component of greater than about 50% and an average molecular weight of the first component and the second component, which is less than about 600, was used, no flux residues were left without conducting cleaning, or the flux residues were removed by water cleaning.

In a case where the flux having an average molecular weight of the first component and the second component, which is about 300 or less, was used, for example, in a case where the first fluxes of 7 to 9, 12, and 26 to 28 were used, no flux residues were left without conducting cleaning. In a case where the flux having an average molecular weight of the first component and the second component, which is greater than about 300 and less than about 600, was used, for example, in a case where the first fluxes of 1 to 3, 5, 10, 11, 13 to 15, 17, 19 to 25, 29 to 31, 33, 35 to 37, 39, 41, 42, 45, and 46 were used, the flux residues were removed by water cleaning.

After it was confirmed that a semiconductor device manufactured using the first fluxes of 1 to 48 has no electrical problems, the following evaluation of connection reliability was conducted. As a result after a temperature cycle test of −55° C. (maintained for 15 minutes) [symbol] 125° C. (maintained for 15 minutes) was conducted through 500 cycles, the resistance was increased about 10% or less, which is favorable. Even after the semiconductor device was left at about 121° C./about 85% RH environment for about 1,000 hours, the resistance was increased about 10% or less similar as in the temperature cycle test, which is favorable. As a result after a high accelerating speed lifetime test was conducted at about 130° C., about 85% RH, and about 4 VBias, even after the lapse of about 96 hours, deterioration in the insulation resistance was not confirmed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A flux comprising:
a first glycol-based polyhydric alcohol having a molecular weight of 300 or less; and
a second glycol-based polyhydric alcohol having a molecular weight of 600 or more.

2. The flux according to claim 1,
wherein the first glycol-based polyhydric alcohol is a polyethylene glycol having a molecular weight of 200 or more, and
the second glycol-based polyhydric alcohol is a polyethylene glycol having a molecular weight of 1,000 or less.

3. The flux according to claim 1,
wherein the first glycol-based polyhydric alcohol is a tetraethylene glycol, and
the second glycol-based polyhydric alcohol is the polyethylene glycol having a molecular weight of 1,000 or less.

4. The flux according to claim 1,
wherein more of the first glycol-based polyhydric alcohols than the second glycol-based polyhydric alcohols is contained in the flux.

5. The flux according to claim 1,
wherein the content of the first glycol-based polyhydric alcohol and the second glycol-based polyhydric alcohol in the flux is 80% or more.

6. The flux according to claim 1,
wherein the flux contains an organic acid or an organic acid anhydride.

7. The flux according to claim 1,
wherein a volatilization temperature of the first glycol-based polyhydric alcohol is lower than a reflow temperature of a SnAg based solder, and
a volatilization temperature of the second glycol-based polyhydric alcohol is higher than the reflow temperature of the SnAg based solder.

8. A method for manufacturing a semiconductor device, comprising:
preparing a semiconductor chip or a semiconductor package and a circuit board; and
bonding the semiconductor chip or the semiconductor package with the circuit board by reflowing an SnAg based solder using a flux which contains a first glycol-based polyhydric alcohol having a molecular weight of 300 or less and a second glycol-based polyhydric alcohol having a molecular weight of 600 or more.

9. The method according to claim 8,
wherein gaps between a plurality of terminals in a bonding portion of the semiconductor chip or the semiconductor package with the circuit board are 100 μm or less.

10. The method according to claim 8,
wherein the first glycol-based polyhydric alcohol is a polyethylene glycol having a molecular weight of 200 or more, and
the second glycol-based polyhydric alcohol is a polyethylene glycol having a molecular weight of 1,000 or less.

11. The method according to claim 8,
wherein the first glycol-based polyhydric alcohol is a tetraethylene glycol, and
the second glycol-based polyhydric alcohol is the polyethylene glycol having a molecular weight of 1,000 or less.

12. The method according to claim 8,
wherein more of the first glycol-based polyhydric alcohols than the second glycol-based polyhydric alcohols is contained in the flux.

13. The method according to claim 8,
wherein the content of the first glycol-based polyhydric alcohol and the second glycol-based polyhydric alcohol in the flux is 80% or more.

14. The method according to claim 8,
wherein the flux contains an organic acid or an organic acid anhydride.

15. The method according to claim 8,
wherein a volatilization temperature of the first glycol-based polyhydric alcohol is lower than a reflow temperature of a SnAg based solder, and
a volatilization temperature of the second glycol-based polyhydric alcohol is higher than the reflow temperature of the SnAg based solder.
